(19) United States
(12) Patent Application Publication
(10) Pub. No.: US 2005/0059233 A1
(43) Pub. Date: Mar. 17, 2005

(54) Process for forming metal damascene structure to prevent dielectric layer peeling

(76) Inventors: Ming-Tsong Wang, Taipei (TW); Di-Shi Su, Taoyuan (TW); Chia-Ming Yang, Taipei (TW); Ching-Ming Tsai, Miaoli (TW)

Correspondence Address: BIRCH STEWART KOLASCH & BIRCH, PO BOX 747, FALLS CHURCH, VA, 22040-0747, US

(21) Appl. No.: 10/660,573

(22) Filed: Sep. 12, 2003

(51) Int. Cl. H01L 21/4763

(52) U.S. Cl. 438/633; 438/634

(57) ABSTRACT

A process for forming a metal damascene structure. First, a cap layer is formed on a first metal layer, and a dielectric layer is formed on the cap layer. Next, the dielectric layer is etched to form a damascene opening. Next, hydrogen-containing plasma, nitrogen-containing plasma, oxygen-containing plasma, or a mixture thereof is used to perform the plasma treatment. Next, a metal is filled in the damascene opening to form a second metal layer. Peeling of the dielectric layer due to remaining impurities is eliminated by the plasma treatment after etching of the damascene opening.

### BACKGROUND OF THE INVENTION

1. Field of the Invention

The present invention relates to a process for forming a metal damascene structure, and more particularly to a process for forming a metal damascene structure to prevent peeling of the dielectric layer, using a special plasma treatment after damascene opening etching.

2. Description of the Prior Art

Due to their high degree of conductivity, aluminum (Al) and aluminum alloy have been important as conductive materials in the development of the integrated circuit (IC). However, integration of semiconductors has rapidly increased, and the conductivity of aluminum and aluminum alloy can no longer satisfy the speed requirements for semiconductor devices. Therefore, copper (Cu) is gradually replacing aluminum as a conductive material, because of its lower resistance and better reliability. In addition, copper is more resistant than aluminum to electromigration. Therefore, in devices with design rule beyond 0.13 μm technology, copper has been adapted for deep submicron ULSI (very large scale integration) metallization and interconnection.

Since copper cannot be patterned by dry etching, a damascene technique is generally used to form copper interconnections. FIGS. 1a to 1d are cross-sections illustrating the process flow of forming a copper damascene structure according to a conventional process. Referring to FIG. 1a, a cap layer 200 such as silicon nitride is formed on a first copper layer 100. Next, an intermetal dielectric (IMD) layer 300 is formed, including sequentially a first dielectric layer 320, an etch stop layer 340 such as silicon oxynitride (SiON), and a second dielectric layer 360. The cap layer 200 is typically used to prevent diffusion of the first copper layer 100 into the overlying IMD 300.

Subsequently, referring to FIG. 1b, a first photoresist mask (not shown) is formed on the second dielectric layer 360 and anisotropic etching is conducted to form a via hole 410 extending through the second dielectric layer 360, the etch stop layer 340, and the first dielectric layer 320. Next, a second photoresist mask (not shown) is formed on the second dielectric layer 360 and anisotropic etching is conducted to form a trench 420 in the second dielectric layer 360 stopping at the etch stop layer 340. Thus far, the via hole 410 and the trench 420 constitutes a dual damascene opening 400.

Subsequently, referring to FIG. 1c, copper is deposited by electrodeposition or electroless deposition to fill the dual damascene opening 400, forming a second copper layer 500. Next, chemical mechanical polishing (CMP) is conducted to planarize the second copper layer 500.

Generally, after anisotropic etching to form the via hole 410 and trench 420, it is difficult to prevent that impurities such as fluorine, chlorine, carbon, oxygen, and so on will remain on the first copper layer 100. Fluorine or chlorine will attack the interface between the first copper layer 100 and the cap layer 200, and oxygen will oxidize the first copper layer 100, forming copper oxide. Moreover, the cap layer 200 will form blisters due to the residual carbon, fluorine, chlorine, or oxygen from the photoresist and the etch process. As a result, peeling of the intermetal dielectric (IMD) 300 (abbreviated to “peeling via”) will result after the substrate is subject to repeated thermal cycles, as shown in FIG. 1d. The peeling via will not only reduce yield, but also diminish reliability. Moreover, severe electromigration (EM) and stress migration (SM) problems occur.

Several methods have been attempted to alleviate the peeling via problem, such as photo stripping without CF₄, fine tuning via/trench etching recipes, revised design rules and so on. The peeling via issue, however, continues to be a problem.

Subramanian et al. in U.S. Pat. No. 6,465,889 discloses a dual damascene technique. Silicon carbide is formed on a copper line to serve as both a cap layer and a BARC (bottom anti-reflective coating). Thus, the dimensional accuracy of the dual damascene structure formed thereon is improved.

Zhao in U.S. Pat. No. 6,071,809 discloses another dual damascene technique. The cap layer is silicon nitride and a pair of CMP hard masks is employed: a silicon dioxide layer and a silicon nitride layer. The silicon dioxide layer protects the underlying silicon nitride layer during the dual damascene etching process, but is subsequently sacrificed during CMP, allowing the silicon nitride layer to act as the CMP hard mask. In this way, delamination of the low-k material is prevented.

Chooi et al. in U.S. Pat. No. 6,436,824 discloses a novel low dielectric constant material for use as a cap layer (passivation layer) for copper. The novel low dielectric constant material can be a carbon-doped silicon nitride layer formed by reacting a substituted ammonia precursor and a substituted organosilane in a plasma-enhanced chemical deposition chamber.

### SUMMARY OF THE INVENTION

An object of the present invention is to solve the above-mentioned problems and provide a process for forming a metal damascene structure. After the damascene opening etching, the present invention performs a special plasma treatment to remove the residual impurities. Thus, peeling of the intermetal dielectric (IMD) layer due to the remaining impurities is solved. Moreover, the present invention can pass the stress migration and electro-migration tests. Moreover, yield and reliability are improved.

To achieve the above object, the process for forming a metal damascene structure according to the present invention includes the following steps. First, a dielectric layer is formed on a substrate. Next, the dielectric layer is etched to form a damascene opening. Next, a plasma treatment is provided to remove remaining impurities on the dielectric layer. Next, a metal is filled in the damascene opening.

According to the present invention, before the dielectric layer is formed, a first metal layer can be formed on the substrate. Thus, the plasma treatment is performed on the surface of the first metal layer. At this time, the plasma treatment can act to remove impurities on the first metal layer and repair the bonding between the first metal layer and the dielectric layer.

According to the present invention, after the first metal layer is formed and before the dielectric layer is formed, a cap layer can be formed on the first metal layer. Thus, the plasma treatment can act to repair the bonding between the first metal layer and the cap layer.

The plasma treatment can use a hydrogen-containing plasma, a nitrogen-containing plasma, an oxygen-containing plasma, or mixtures thereof.

According to a first preferred embodiment of the present invention, etching of the damascene opening is conducted by fluorine containing plasma or a chlorine-containing plasma, and the plasma treatment uses hydrogen-containing plasma. For example, hydrogen (H₂) plasma, ammonia (NH₃) plasma, H₂/NH₃ plasma, or H₂/N₂ plasma can be used. The hydrogen bond of the hydrogen-containing plasma is ionized to form ionized hydrogen atoms. These ionized hydrogen atoms can deoxidize undesired copper oxide and react with free fluorine or chlorine. Therefore, dielectric layer peeling due to residual fluorine or chlorine can be eliminated.

According to a second preferred embodiment of the present invention, the cap layer is nitride and the plasma treatment uses nitrogen-containing plasma. For example, nitrogen (N₂) plasma, ammonia (NH₃) plasma, H₂/N₂ plasma, or H₂/NH₃ plasma can be used. The nitrogen-containing plasma can repair the bonding between the first metal layer and the cap layer (nitride). Thus, the first metal layer and the cap layer have good adhesion, and peeling of the dielectric layer can be eliminated.

According to a third preferred embodiment of the present invention, the photoresist mask for the damascene opening etching contains carbon, and the plasma treatment uses oxygen-containing plasma such as N₂O plasma or oxygen (O₂) plasma. The oxygen-containing plasma can react with the remaining carbon, thus preventing formation of blisters due to remaining carbon.

### BRIEF DESCRIPTION OF THE DRAWING

FIGS. 1a to 1d are cross-sections illustrating the process flow of forming a copper damascene structure according to a conventional process

FIG. 2 is a flowchart of forming a metal damascene structure according to the present invention.

FIGS. 3a to 3c are cross-sections illustrating the process flow of forming a metal damascene structure according to a preferred embodiment of the present invention.

FIG. 4a is a top view and FIG. 4b is a side view of the testing structure for electromigration (EM) and stress migration (SM).

FIG. 5 shows the EM test result for the testing structures of the present invention and the Comparative Example.

FIG. 6 shows the SM test result for the testing structure of the Comparative Example.

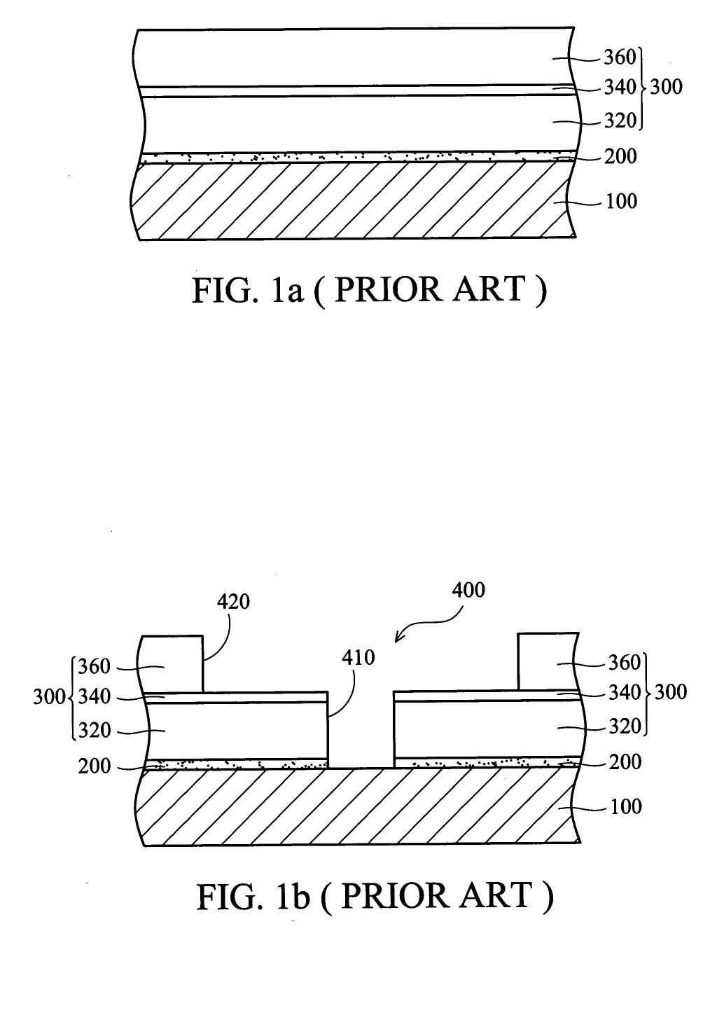

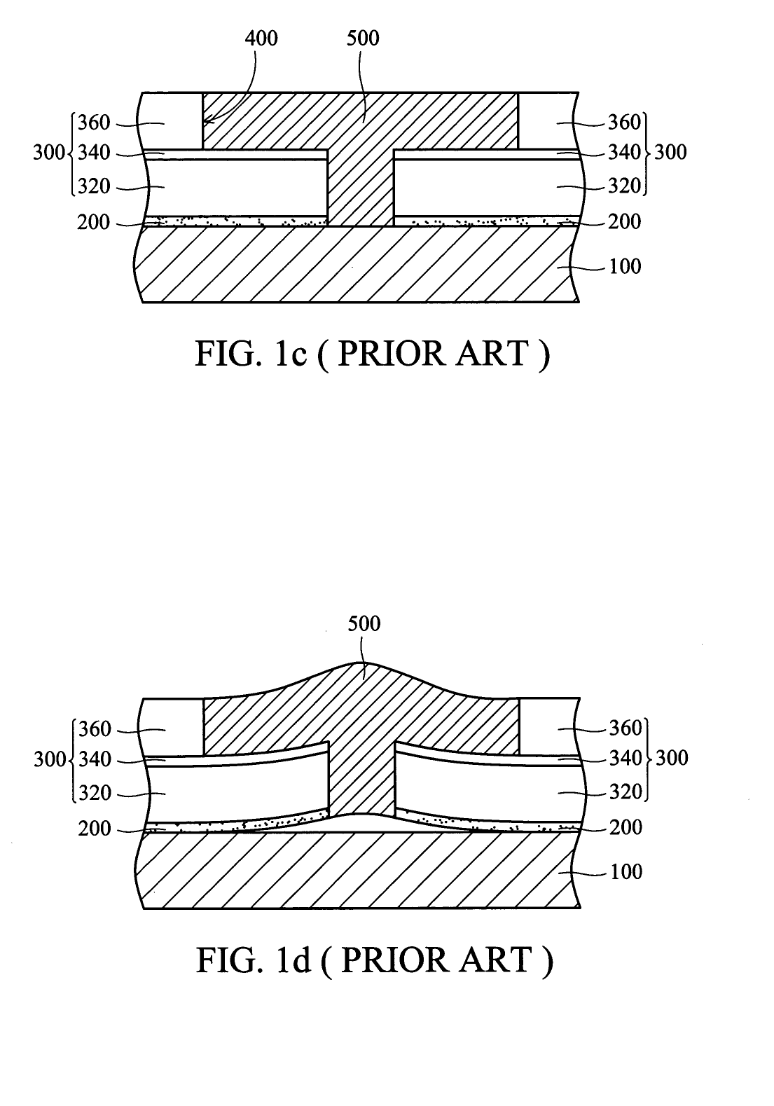

### DETAILED DESCRIPTION OF THE INVENTION

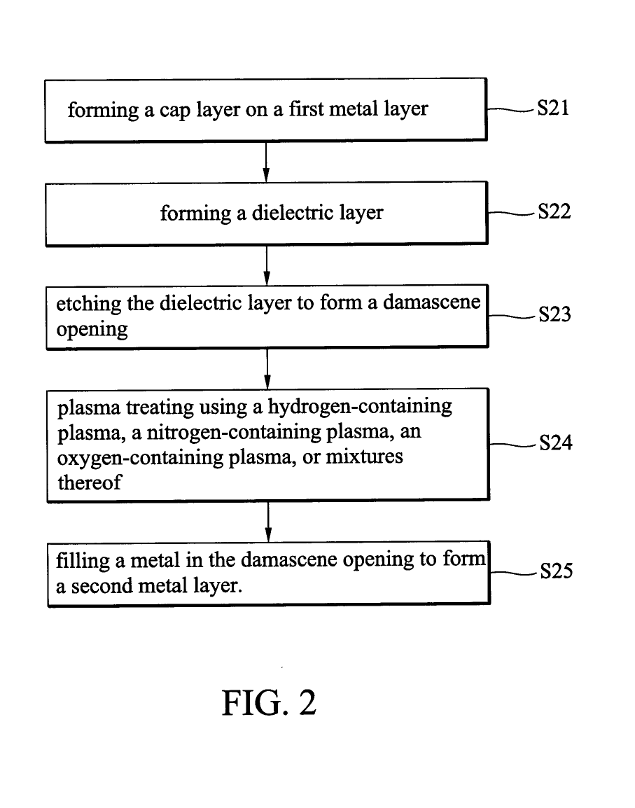

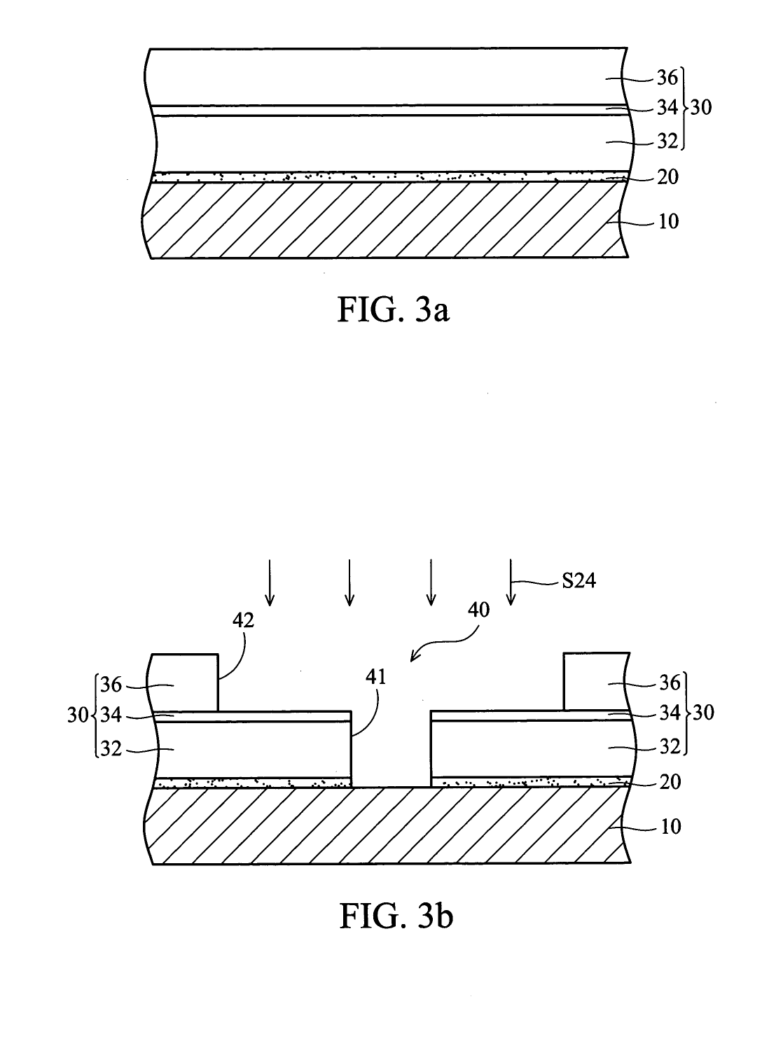

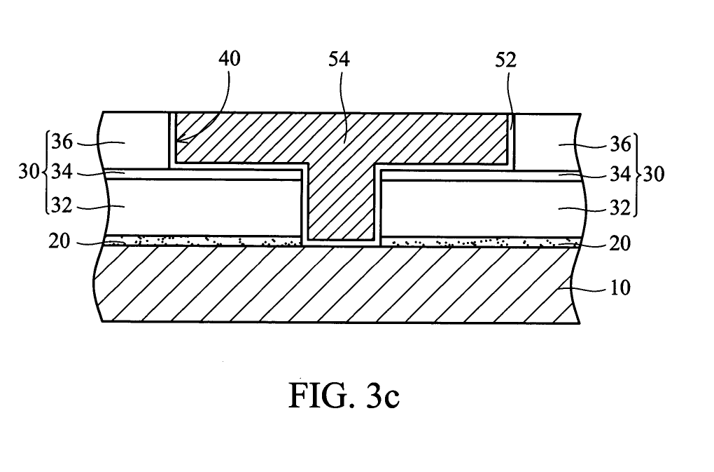

FIG. 2 is a flowchart of forming a metal damascene structure according to the present invention. FIGS. 3a to 3c are cross-sections illustrating the process flow of forming a metal damascene structure according to a preferred embodiment of the present invention.

A dual damascene process is taken as an example in the following descriptions. However, a single damascene process is also within the scope of the present invention. Referring to FIGS. 2 and 3a, first, a cap layer 20 is formed on a first metal layer 10 (step S21). The cap layer 20 is used to prevent diffusion of the first metal layer 10 into the overlying intermetal dielectric (IMD) to be formed in a later step. The cap layer 20 can be nitride or silicon carbide (SiC). Representative examples of the nitride cap layer include silicon nitride, titanium nitride (TiN), tungsten nitride (WN), titanium silicon nitride (TiSiN) and tungsten silicon nitride (WSiN).

Subsequently, still referring to FIGS. 2 and 3a, a dielectric layer (intermetal dielectric layer; IMD) 30 is formed on the cap layer (step S22). The dielectric layer can include three sequentially formed layers, e.g., a first dielectric layer 32, an etch stop layer 34, and a second dielectric layer 36. The first and second dielectric layers 32 and 36 can be silicon oxide or silicon nitride formed by chemical vapor deposition (CVD). Alternatively, the first and second dielectric layers 32 and 36 can be a low dielectric constant material (k=3.9 or under), for example, an organic polymer material such as FLARE, PAE-2, and SILK, a non-organic material such as FSG (fluorosilicate glass) and HSQ (hydrogen silsesquioxane), black diamond, or high black diamond (HBD). The etch stop layer 34 can be silicon nitride or silicon oxynitride (SiON).

Subsequently, referring to FIGS. 2 and 3b, the dielectric layer 30 is etched to form a damascene opening 40 (step S23). For example, a via-first technique can be performed. First, a first photoresist mask (not shown) is formed on the second dielectric layer 36 and a first anisotropic etching is conducted to form a via hole 41 extending through the second dielectric layer 36, the etch stop layer 34, and the first dielectric layer 32. Next, a second photoresist mask (not shown) is formed on the second dielectric layer 36 and a second anisotropic etching is conducted to form a trench 42 in the second dielectric layer 36 stopping at the etch stop layer 34. Thus far, the via hole 41 and the trench 42 constitutes the dual damascene opening 40.

Subsequently, still referring to FIGS. 2 and 3b, a special plasma treatment of the present invention is performed (step S24). The special plasma treatment can remove remaining impurities on the dielectric layer 30. For example, hydrogen-containing plasma, nitrogen-containing plasma, oxygen-containing plasma, or a mixture thereof can be used for the special plasma treatment. The flow rate of the plasma for the plasma treatment can be 20 sccm to 300 sccm.

The above-mentioned first anisotropic etching to form the via hole 41 and the second anisotropic etching to form the trench 42 can be performed using a fluorine-containing plasma or a chlorine-containing plasma. For example, CF₄ can be used. As described in the prior art, fluorine, or chlorine impurities will remain after via hole and trench etching, which attack the interface between the first metal layer 10 and the cap layer 20. As a result, peeling of the dielectric layer 30 will occur after the substrate is subject to repeated thermal cycles. To prevent the dielectric layer peeling, the present invention can perform a plasma treatment with hydrogen-containing plasma. The hydrogen-containing plasma can be hydrogen (H₂) plasma or ammonia (NH₃) plasma.

The hydrogen bond of the hydrogen-containing plasma is ionized to form ionized hydrogen atoms. These ionized hydrogen atoms can deoxidize undesired copper oxide and react with free fluorine or chlorine under plasma and high temperature (about 400° C.) chamber conditions. Therefore, dielectric layer peeling due to the residual fluorine or chlorine can be eliminated.

In addition, when the cap layer 20 is nitride, the plasma treatment of the present invention can use nitrogen-containing plasma, such as nitrogen (N₂) plasma or ammonia (NH₃) plasma, after the damascene opening 40 etching. The nitrogen-containing plasma can repair the bonding between the first metal layer 10 (such as Cu) and the cap layer 20 (nitride). Thus, the first metal layer 10 and the cap layer 20 have good adhesion, and peeling of the dielectric layer 30 can be solved.

In addition, the photoresist mask generally contains carbon. After etching of the damascene opening 40 (step 23), the cap layer 20 will form blisters due to the residual carbon, fluorine, chlorine, or oxygen from the photoresist and the etch process. The present invention can perform a plasma treatment with oxygen-containing plasma, such as N₂O plasma or oxygen (O₂) plasma, after etching of the damascene opening 40. The oxygen-containing plasma can react with the remaining carbon, thus preventing formation of blisters.

Subsequently, referring to FIGS. 2 and 3c, a metal is filled in the damascene opening 40 to form a second metal layer 54 (step 25). Before the second metal layer 54 is formed, a barrier layer 52, such as Ta or TaN, can be first formed to line the damascene opening 40. A seed layer (not shown) can then be formed on the barrier layer 52, and then the metal layer 54 is formed. The metal layer 54 can be copper or copper alloy formed by electroless deposition or electrodeposition. Next, the metal layer 54 is planarized by chemical mechanical polishing (CMP). The seed layer can be copper or alloys of copper with elements such as magnesium, aluminum, zinc, zirconium, tin, nickel, palladium, gold or silver.

### EXAMPLE

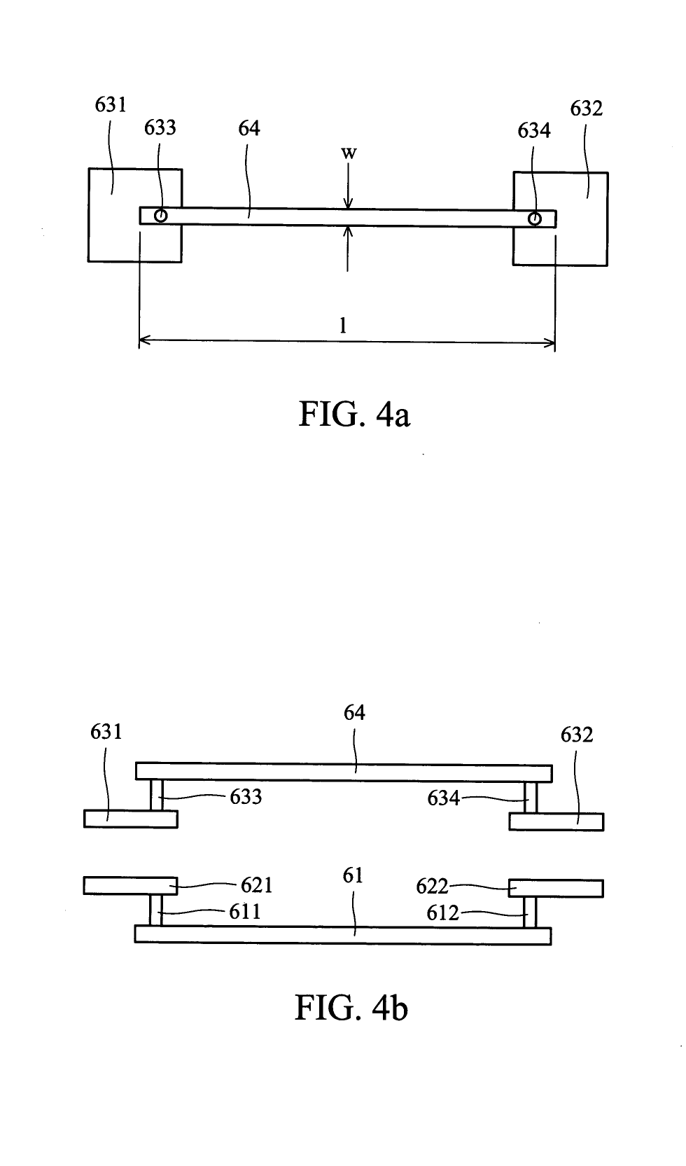

According to the above-mentioned process of the present invention, after the dielectric layer was etched to form a damascene opening, a plasma treatment using H₂/NH₃ plasma was performed. Then, copper was filled in the damascene opening to complete metallization and obtain a testing structure shown in FIGS. 4a and 4b. The copper lines are capped by SiN cap layers (not shown).

FIG. 4a is a top view and FIG. 4b is a side view of the testing structure for electromigration (EM) and stress migration (SM). The testing structure includes four levels of metal. Symbol 61 indicates a metal line (the first level), and symbols 621 and 622 indicate metal pads (the second level), in which the pad 621 connects the metal line 61 via a plug 611 and the pad 622 connects the metal line 61 via a plug 612. Symbols 631 and 632 indicate metal pads (the third level), and symbol 64 indicates a metal line (the fourth level), in which the pad 631 connects the metal line 64 via a plug 633 and the pad 632 connects the metal line 64 via a plug 634. The width (w) of the metal lines 61 and 64 is 3.5 μm and the length (l) is 55 μm. The plugs (or via holes) 611, 612, 633 and 634 have a diameter of 0.5 μm.

### COMPARATIVE EXAMPLE

The same procedures as described in the Example were employed except that after the dielectric layer was etched to form a damascene opening and before copper is filled, no plasma treatment was performed.

EM Testing

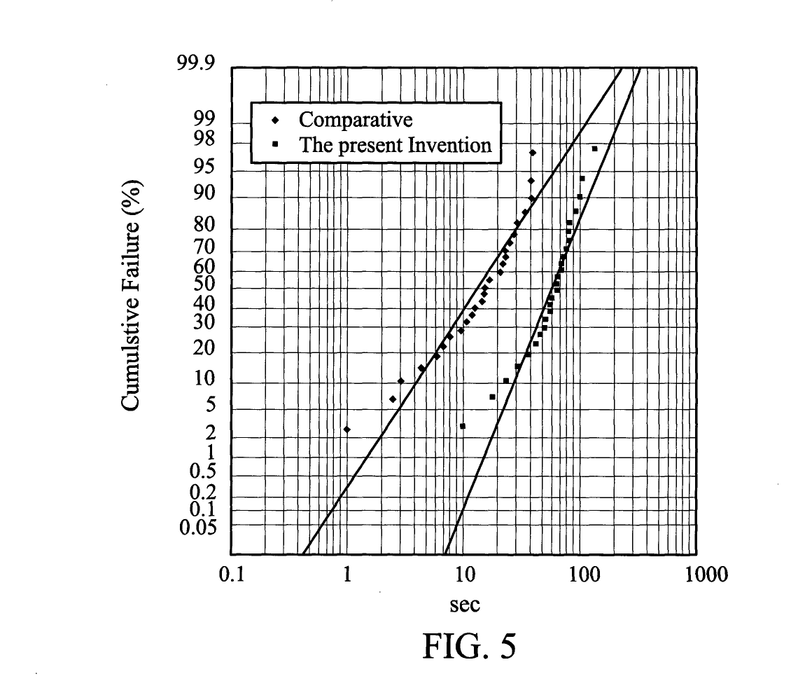

The testing structures obtained from the Example (the present invention) and Comparative Example were stressed at a constant current of 5 mega A/cm² at 450° C. respectively for EM testing. The results are shown in FIG. 5 and Table 1. It can be seen that TTF (time to failure) (t₅₀) of the testing structure of the present invention is increased from 13 sec to 59 sec by the H₂/NH₃ plasma treatment.

TABLE 1

| | | The present |
|---|---|---|
| Results | Comparative | invention |
| Sigma | 0.94 | 0.56 |
| t₅₀ (sec) | 13.31 | 59.16 |
| t_{0.1} (sec) | 0.73 | 10.33 |
| Jmax (mA) | 0.301 | 1.129 |

SM Testing

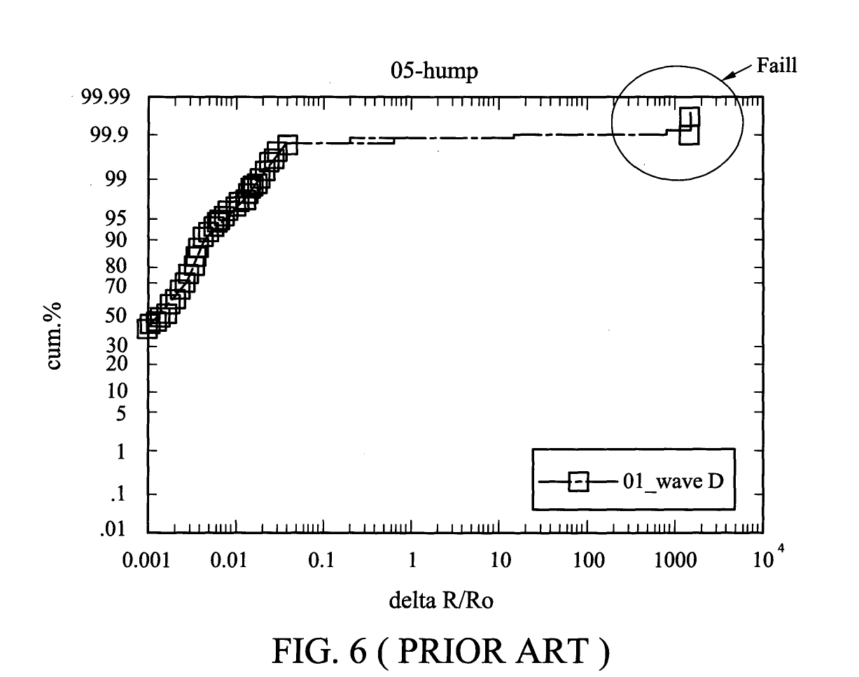

The testing structures obtained from the Example (the present invention) and Comparative Example were stored in a vacuum oven within 100° C.-300° C. for 3 weeks respectively for SM testing. The testing structure of the Comparative Example failed to pass the SM test as shown in FIG. 6. However, it is found that the testing structure of the present invention passed the SM test without any failure.

In conclusion, after etching to form the damascene opening and before metal is filled in the opening, the present invention performs a plasma treatment with hydrogen-containing plasma, nitrogen-containing plasma, oxygen-containing plasma, or a mixture thereof. Thus, remaining impurities can be removed and peeling of the dielectric layer due to remaining impurities is eliminated. Additionally, the testing structure obtained from employing the plasma treatment of the present invention passes the electromigration (EM) and stress migration (SM) tests.

The foregoing description of the preferred embodiments of this invention has been presented for purposes of illustration and description. Obvious modifications or variations are possible in light of the above teaching. The embodiments chosen and described provide an excellent illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

1. A process for forming a metal damascene structure, comprising the following steps:
forming a dielectric layer overlying a first metal layer;
etching the dielectric layer to form a damascene opening and expose the first metal layer, wherein impurities are formed on the exposed first metal layer;
treating the exposed first metal layer using a plasma containing nitrogen and oxygen to remove the impurities thereon; and
filling a metal in the damascene opening.

2. The process as claimed in claim 1, wherein the plasma further contains hydrogen.

3. (Cancelled).

4. (Cancelled).

5. The process as claimed in claim 1, wherein the plasma is N₂O plasma.

6. (Cancelled).

7. The process as claimed in claim 1, wherein the damascene opening is a via.

8. The process as claimed in claim 7, wherein the damascene opening further comprises a trench above the via.

9. The process as claimed in claim 8, wherein the metal filling step includes filling copper or copper alloy in the trench and the via.

10. (Cancelled).

11. The process as claimed in claim 1, wherein the first metal layer is copper or copper alloy.

12-14. (Cancelled).

15. The process as claimed in claim 1, after the first metal layer is formed and before the dielectric layer is formed, further comprising forming a cap layer on the first metal layer.

16. The process as claimed in claim 15, wherein the cap layer is nitride or silicon carbide.

17. (Cancelled).

18. A process for forming a metal damascene structure, comprising the following steps:
forming a cap layer on a first metal layer;
forming a dielectric layer on the cap layer;
etching the dielectric layer and the underlying cap layer with fluorine-containing plasma or chlorine-containing plasma to form a damascene opening and expose the first metal layer, wherein impurities are formed on the exposed first metal layer;
plasma treating the exposed first metal layer using a plasma containing nitrogen and oxygen to remove the impurities thereon; and
filling a metal in the damascene opening.

19. The process as claimed in claim 18, wherein the plasma further contains hydrogen.

20. The process as claimed in claim 18, wherein the plasma is an N₂O plasma.

21. The process as claimed in claim 18, wherein the damascene opening is a via.

22. The process as claimed in claim 21, wherein the damascene opening further comprises a trench above the via.

23. The process as claimed in claim 22, wherein the metal filling step includes filling copper or copper alloy in the trench and the via.

24. The process as claimed in claim 18, wherein the first metal layer is copper or copper alloy.

25. The process as claimed in claim 18, wherein the cap layer is nitride or silicon carbide.

26-33. (Cancelled).

34. A process for forming a metal damascene structure, comprising the following steps:
forming a cap layer on a first metal layer;
forming a dielectric layer on the cap layer;
forming a photoresist pattern on the dielectric layer, wherein the photoresist pattern contains carbon;
etching the dielectric layer and the underlying cap layer using the photoresist pattern as a mask to form a damascene opening and expose the first metal layer, wherein impurities are formed on the exposed first metal layer;
plasma treating the exposed first metal layer using a plasma containing nitrogen and oxygen to remove the impurities thereon; and
filling a metal in the damascene opening.

35. The process as claimed in claim 34, wherein the etching step uses fluorine-containing plasma or chlorine-containing plasma.

36. The process as claimed in claim 34, wherein the plasma is an N₂O plasma.

37. The process as claimed in claim 34, wherein the damascene opening is a via.

38. The process as claimed in claim 37, wherein the damascene opening further comprises a trench above the via.

39. The process as claimed in claim 38, wherein the metal filling step includes filling copper or copper alloy in the trench and the via.

40. The process as claimed in claim 34, wherein the cap layer is nitride or silicon carbide.
